(19) United States
(12) Patent Application Publication
(10) Pub. No.: US 2025/0192122 A1
(43) Pub. Date: Jun. 12, 2025

(54) PACKAGE STRUCTURE

(71) Applicant: TXC Corporation, Taipei City (TW)

(72) Inventors: Shih-Yung Pao, Taipei City (TW); Chih-Hsun Chen, Taipei City (TW); Tzu-Hsiu Peng, Taipei City (TW); Sheng-Hsiang Kao, Taipei City (TW)

(73) Assignee: TXC Corporation, Taipei City (TW)

(21) Appl. No.: 18/404,800

(22) Filed: Jan. 4, 2024

(30) Foreign Application Priority Data
Dec. 6, 2023 (TW) 112147449

(51) Int. Cl. H01L 25/16; H01L 23/00; H01L 23/48

(52) U.S. Cl. CPC H01L 25/165; H01L 23/481; H01L 24/08; H01L 24/16; H01L 2224/08235; H01L 2224/16225; H01L 2924/1433; H01L 2924/15787; H01L 2924/16196; H01L 2924/16787; H01L 2924/17787; H01L 2924/19011; H01L 2924/19105

(57) ABSTRACT

A package structure includes a first layer, a second layer and a third layer. The second layer includes an outer frame, a resonator and a chip. The second layer is arranged between the first layer and the third layer. The outer frame, the first layer and the third layer are constituted a rectangular accommodation portion. The resonator and the chip are located in the rectangular accommodation portion. The chip is located at a side of the resonator, and is electrically connected to the third layer and the resonator through a plurality of conductive components on the chip. A package structure in which the chip is located below the resonator is also provided.

### CROSS-REFERENCE TO RELATED APPLICATION

This application claims the priority benefit of Taiwan application serial no. 112147449, filed on Dec. 6, 2023. The entirety of the above-mentioned patent application is hereby incorporated by reference herein and made a part of this specification.

### BACKGROUND

### Technical Field

The disclosure relates to a package structure.

### Description of Related Art

With the development trend of quartz frequency devices toward high stability, miniaturization, thinness and wafer-level package (WLP) technology, a configuration relationship of components is crucial. For example, when a chip is arranged on an outer surface of the wafer-level package structure, an underfill is often used to cover conductive components (such as gold balls) thereon. However, the aforementioned method cannot provide the conductive component with effectively protection, such as a defect is generated from failure to reliably cover, such that it may lead to the product failure along the defect during subsequent processes.

### SUMMARY

The disclosure provides a package structure that the probability of the product failure can be effectively reduced while the thinness of product performance is achieved.

A package structure of the disclosure includes a first layer, a second layer, and a third layer. The second layer includes an outer frame, a resonator, and a chip. The second layer is arranged between the first layer and the third layer. The outer frame, the first layer and the third layer are constituted a rectangular accommodation portion. The resonator and the chip are located in the rectangular accommodation portion. The chip is located at a side of the resonator, and the chip is electrically connected to the third layer and the resonator through a plurality of conductive components thereon.

A package structure of the disclosure includes a first layer, a second layer, and a third layer. The second layer includes an outer frame, a resonator, and a chip. The second layer is arranged between the first layer and the third layer. The outer frame, the first layer and the third layer are constituted a rectangular accommodation portion. The resonator and the chip are located in the rectangular accommodation portion. The chip is located below the resonator, and the chip is electrically connected to the third layer and the resonator through a plurality of conductive components thereon.

Based on the above, through the design of the stacked structure and the rectangular

accommodation portion, the disclosure can reliably encapsulate the resonator and the chip and ensure that the conductive components on the chip are completely protected, thereby the probability of the product failure is effectively reduced while the thinness of product performance is achieved.

In order to make the above-mentioned features and advantages of the present disclosure comprehensible, embodiments accompanied with drawings are described in detail below.

### BRIEF DESCRIPTION OF THE DRAWINGS

FIG. 1 is a schematic external view of a package structure according to an embodiment of the disclosure.

FIG. 2 is a schematic exploded view of FIG. 1.

FIG. 3 is a schematic side view of the interior of FIG. 1.

FIG. 4A, FIG. 4B, FIG. 4C, FIG. 4D, FIG. 4E, and FIG. 4F are schematic top views from a bottom portion of a third layer to a top portion of a first layer in FIG. 2, respectively.

FIG. 5 is a schematic cross-sectional view along the section line A-A′ after FIG. 4A to FIG. 4F are stacked.

FIG. 6 is a schematic cross-sectional view along the sectional line B-B′ after FIG. 4A to FIG. 4F are stacked.

FIG. 7 is a schematic cross-sectional view along the section line C-C′ after FIG. 4A to FIG. 4F are stacked.

FIG. 8 is a schematic external view of a package structure according to another embodiment of the disclosure.

FIG. 9 is a schematic exploded view of FIG. 8.

FIG. 10 is a schematic side view of the interior of FIG. 8.

FIG. 11 is a schematic top view of the top portion of the third layer in FIG. 8.

### DESCRIPTION OF THE EMBODIMENTS

In the following detailed description, for purposes of explanation and not limitation, exemplary embodiments disclosing specific details are set forth in order to provide a thorough understanding of the various principles of the disclosure. It will be apparent, however, to one of ordinary skill in the art, having been benefited from this disclosure, that the present disclosure may be practiced in other embodiments that depart from the specific details disclosed herein. Furthermore, descriptions of commonly-known devices, methods, and materials may be omitted so as not to shift the focus from the description of the various principles of the present disclosure.

Exemplary embodiments of the disclosure are fully described below with reference to the drawings, but the disclosure may further be implemented in many different forms and should not be construed as limited to the embodiments described herein. In the drawings, for the sake of clarity, the sizes and thicknesses of regions, parts and layers may not be drawn in actual scale. In order to facilitate understanding, the same elements in the following description are described with the same symbols.

Directional terms (e.g., up, down, right, left, front, back, top and bottom) as used herein are merely used with reference to the drawings and are not intended to imply absolute orientation.

It should be understood that, although the terms “first”, “second”, “third”, or the like may be used herein to describe various elements, components, regions, layers, and/or portions, these elements, components, regions, and/or portions should not be limited by these terms. These terms are only used to distinguish one element, component, region, layer, or portion from another element, component, region, layer, or portion.

Unless otherwise defined, all terms (including technical and scientific terms) used herein have the same meaning as commonly understood by those of ordinary skill in the field to which the disclosure pertains.

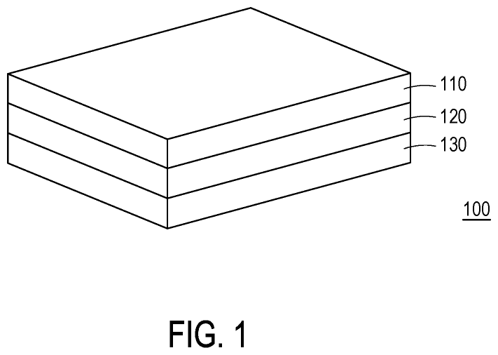

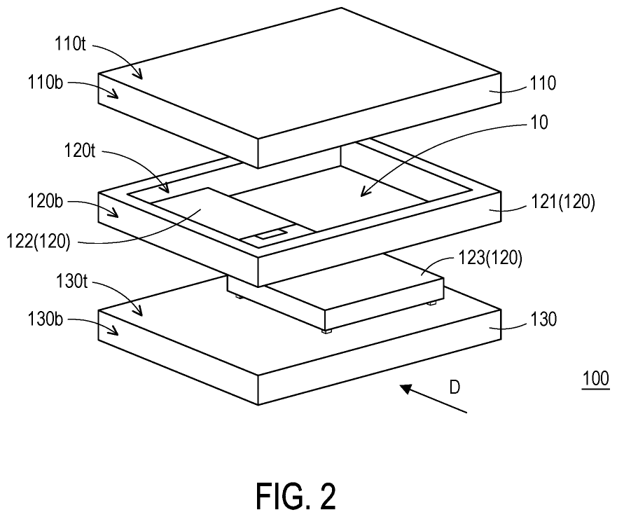

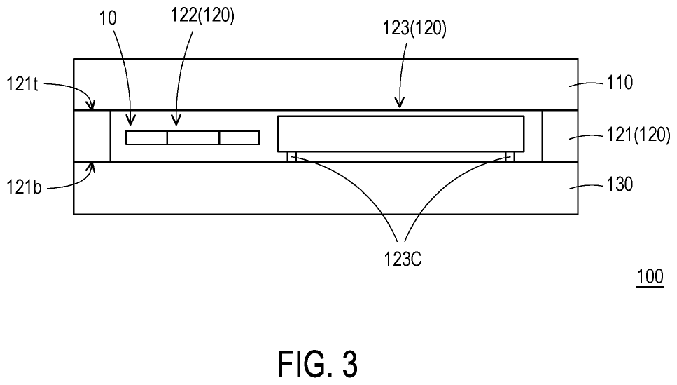

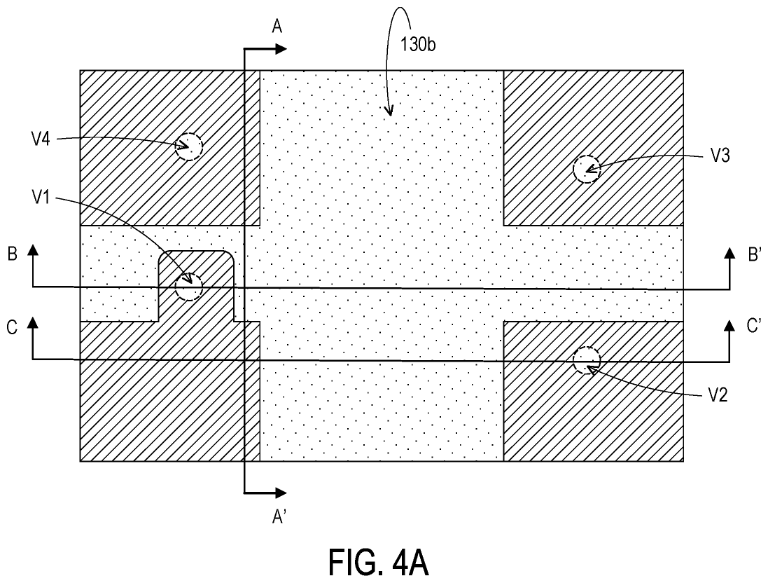

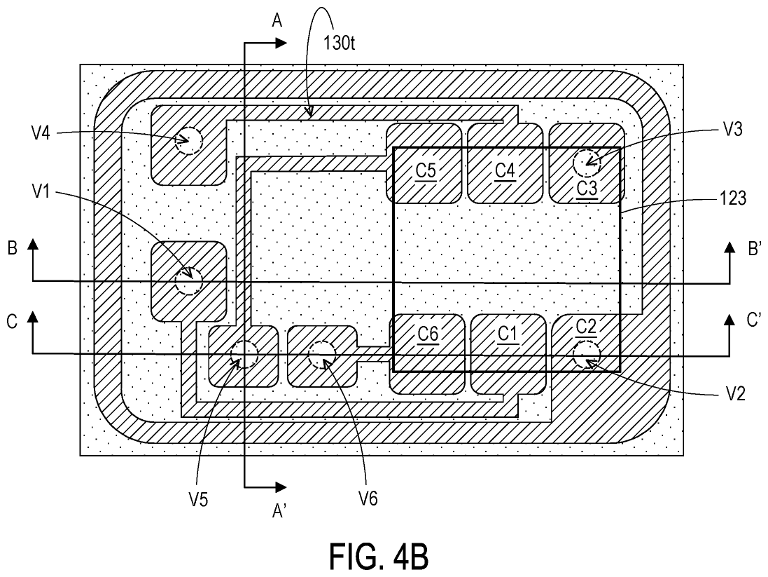

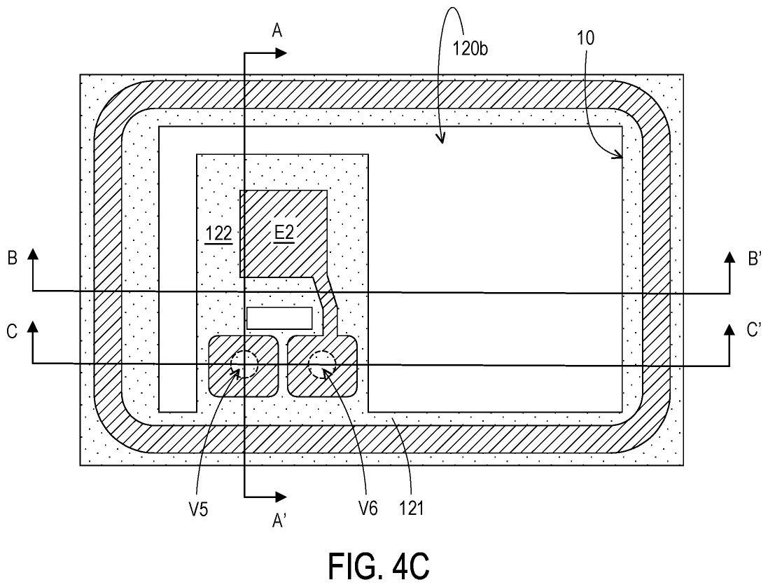

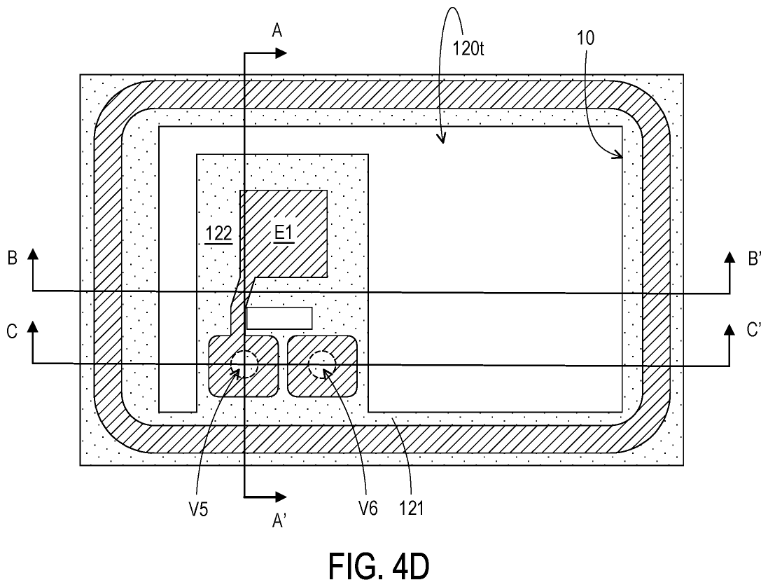

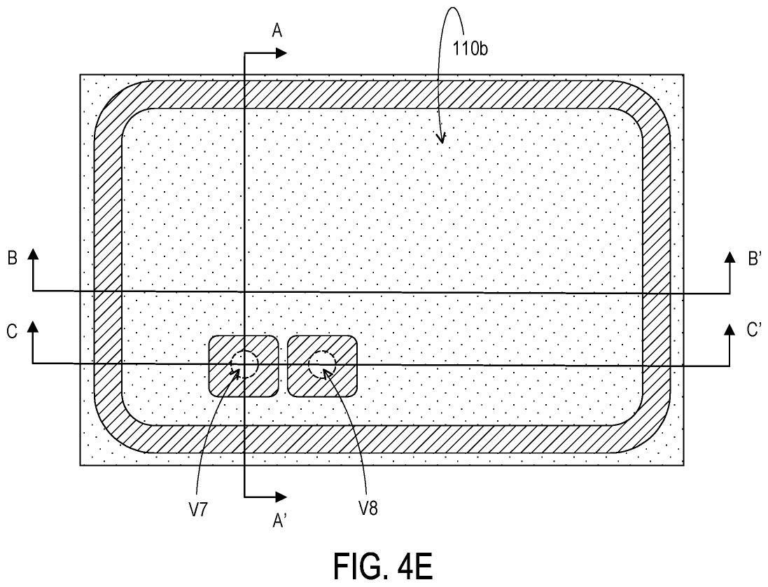

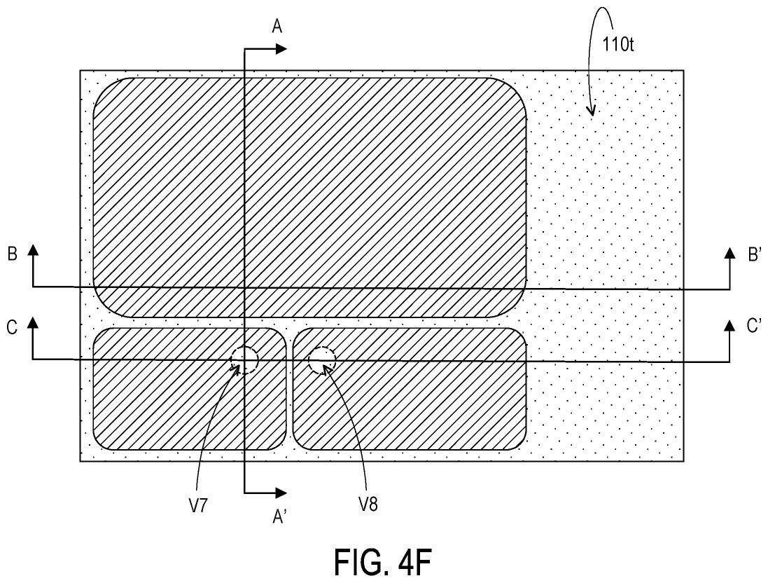

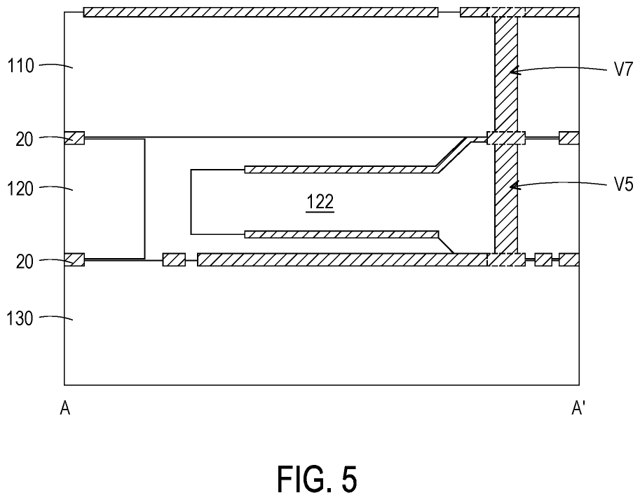

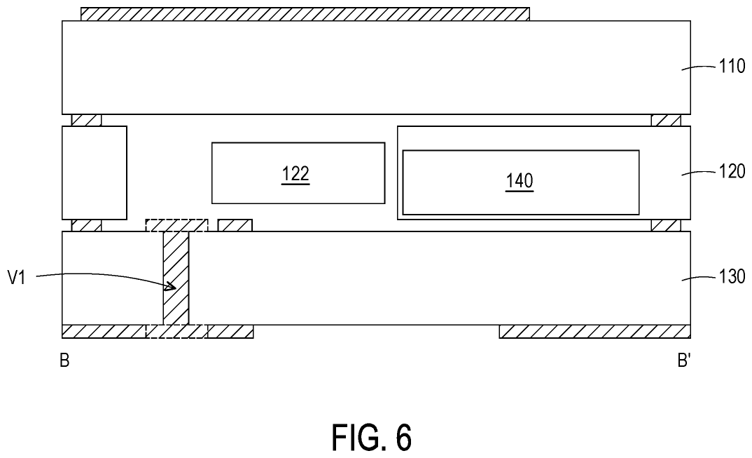

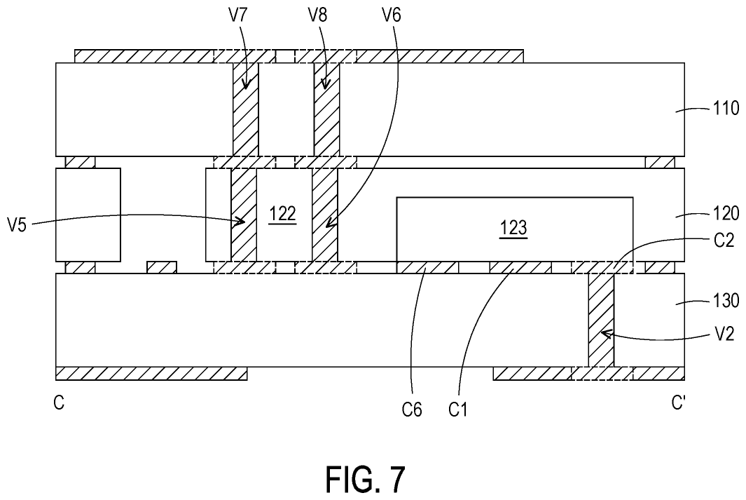

FIG. 1 is a schematic external view of a package structure according to an embodiment of the disclosure. FIG. 2 is a schematic exploded view of FIG. 1. FIG. 3 is a schematic side view of the interior of FIG. 1. FIG. 4A, FIG. 4B, FIG. 4C, FIG. 4D, FIG. 4E, and FIG. 4F are schematic top views from a bottom portion of a third layer to a top portion of a first layer in FIG. 2, respectively. FIG. 5 is a schematic cross-sectional view along the section line A-A′ after FIG. 4A to FIG. 4F are stacked. FIG. 6 is a schematic cross-sectional view along the sectional line B-B′ after FIG. 4A to FIG. 4F are stacked. FIG. 7 is a schematic cross-sectional view along the section line C-C′ after FIG. 4A to FIG. 4F are stacked. In here, FIG. 3 is a side portion viewed from a direction D after assembly in FIG. 2.

Referring to FIG. 1 to FIG. 3. In this embodiment, the package structure 100 includes a first layer 110, a second layer 120, and a third layer 130, wherein the second layer 120 is arranged between the first layer 110 and the third layer 130, and the second layer 120 includes an outer frame 121, a resonator 122 and a chip 123. It should be noted that FIG. 2 only clearly illustrates the bonding position of the chip 123 through the exploded view, and not represented that it is included in the third layer 130. As shown in FIG. 3, the chip 123 is included in the second layer 120 after assembly.

In some embodiments, the chip 123 is an integrated circuit (IC) and the type thereof includes ASIC (Application specific integrated circuit) and integrated circuit (IC) produced by semiconductor technology, but the disclosure is not limited thereto.

In addition, the outer frame 121, the first layer 110 and the third layer 130 are constituted

a rectangular accommodation portion 10, the resonator 122 and the chip 123 are located in the rectangular accommodation portion 10, and the chip 123 is located at a side of the resonator 122, wherein the chip 123 is electrically connected to the third layer 130 and the resonator 122 through a plurality of conductive components 123C on the chip 123. Accordingly, through the design of the stacked structure and the rectangular accommodation portion 10, the disclosure can reliably encapsulate the resonator 122 and the chip 123 and ensure that the conductive components 123C on the chip 123 are completely protected, thereby the probability of the product failure is effectively reduced while the thinness of product performance is achieved. In here, the conductive components 123C may be gold balls or the like, and the conductive components 123C in the structure of this embodiment may not be in contact with air, therefore, there is no underfill. In addition, as shown in FIG. 3, the aforementioned rectangular accommodation portion 10 has a square structure instead of an L-shape or a convex shape.

Furthermore, when faced with the subsequent process such as a molding process, the rectangular accommodation portion 10 comprehensively protects the conductive components 123C, which can reduce the probability of the product failure by the stress generated from the process causing deformation or even an interface damage of the conductive components 123C, and since the chip is not protruded on the outer surface of the package structure, such that a thickness of the package structure 100 can be reduced to meet the thinness requirement, but the disclosure is not limited thereto.

In this embodiment, as shown in FIG. 2, the first layer 110 and the third layer 130 are both cuboid solid structures (not U-shaped, inverted U-shaped or the like), that is to say, neither the first layer 110 nor the third layer 130 has the grooves, so the difficulty of bonding stacked structure can be reduced. Meanwhile, since an etching process for forming the grooves can be omitted, the process can also be simplified, but the disclosure is not limited thereto.

In some embodiments, a material of the first layer 110, the outer frame 121, the resonator 122 and the third layer 130 are composed of quartz, therefore, the package structure 100 can be a wafer-level package quartz crystal oscillator (Xtal Oscillator), for example, the first layer 110 and the third layer 130 are both circuit substrates, while the resonator 122 and the outer frame 121 can be an integrated structure, that is, as shown in FIG. 4C and FIG. 4D, the outer frame 121 is directly physically connected to the resonator 122. There is no bonding interface between the outer frame 121 and the resonator 122. Therefore, an adhesive such as bonding glue can be omitted, which can save manufacturing costs. and steps, but the disclosure is not limited thereto, wherein although the resonator 122 is shown in FIG. 4C and FIG. 4D to be physically connected to only one side of the outer frame 121, in an embodiment not shown, the resonator may be physically connected to at least two sides or more (such as three or four sides) of the outer frame according to actual design requirements.

In some embodiments, the package structure 100 may be formed by the following steps. First, the circuits and the components required for each layer are formed on three quartz wafers through a suitable process (such as a photolithography process), respectively, and a plurality of chips 123 are arranged on the wafer which served as the third layer 130. Then, the three quartz wafers are bonded to each other through a bonding material (such as the bonding components 20 in FIG. 5, for example, a suitable adhesive material) and then a singulation or dicing process is performed to isolate a plurality of the package structures 100, wherein the gaps between adjacent wafers will be generated by the bonding components 20.

In some embodiments, a top surface 121t and a bottom surface 121b opposite to each other of the outer frame 121 are in direct contact with the first layer 110 and the third layer 130, respectively. A thickness of the resonator 122 and a thickness of the chip 123 are not greater than a thickness of the outer frame 121, and the resonator 122 and the chip 123 will not be in direct contact with the first layer 110, but the disclosure is not limited thereto.

In some embodiments, the package structure 100 only be composed of the first layer 110, the second layer 120 and the third layer 130, but the disclosure is not limited thereto.

In order to make the circuit layout in the aforementioned package structure 100 more obvious and easy to understand, the following is explained in detail through FIG. 4A to FIG. 4F and FIG. 5 to FIG. 7, but this is not used to limit the circuit layout of this disclosure, as long as the chip 123 can be electrically connected to the third layer 130 and the resonator 122 through the conductive components 123C thereon within the scope of the disclosure.

In here, FIG. 4A is corresponded to a circuit layout of a bottom portion 130b of the third layer 130, FIG. 4B is corresponded to a circuit layout of a top portion 130t of the third layer 130, FIG. 4C is corresponded to a circuit layout of a bottom portion 120b of the second layer 120, FIG. 4D is corresponded to a circuit layout of a top portion 120t of the second layer 120, FIG. 4E is corresponded to a circuit layout of a bottom portion 110b of the first layer 110, FIG. 4F is corresponded to a circuit layout of a top portion 110t of the first layer 110, and FIG. 5 to FIG. 7 are views obtained by stacking these views in the vertical direction and taking cross-section.

In this embodiment, the first layer 110, the second layer 120 and the third layer 130 are electrically connected to each other through a plurality of vias, for example, as shown in FIG. 4A, FIG. 4B and FIG. 7, the conductive components (not shown) of the chip 123 arranged on a surface of the top portion 130t of the third layer 130 through a flip chip can be bonded to a bonding pad C1, a bonding pad C2, a bonding pad C3, a bonding pad C4, a bonding pad C5, a bonding pad C6, and the bonding pad C1, the bonding pad C2, the bonding pad C3, the bonding pad C4, the bonding pad C5, the bonding pad C6 are located on the surface of the top portion 130t of the three layer 130, wherein the bonding pad C1, the bonding pad C2, the bonding pad C3 and the bonding pad C4 are physically contacted and electrically connected to a via V1, a via V2, a via V3, and a via V4 penetrated through the third layer 130, respectively. The via V1, the via V2, the via V3, and the via V4 are then physically contacted downwards and electrically connected to the circuits of the bottom portion 130b of the third layer 130.

On the other hand, as shown in FIG. 4B to FIG. 4D and FIG. 5 to FIG. 7, the bonding pad C5 and the bonding pad C6 are respectively electrically connected to a via V5 and a via V6 penetrated through the second layer 120 through the circuits of the top portion 130t of the third layer 130. The via V5 and the via V6 are physically contacted and electrically connected to the circuits of the top portion 120t of the second layer 120, wherein the via V5 and the via V6 will be electrically connected to a second electrode E2 of the resonator 122 located in the bottom portion 120b of the second layer 120 and a first electrode El of the resonator 122 located in the top portion 120t of the second layer 120 through other circuits.

Next, as shown in FIG. 4E to 4F and FIG. 5 to FIG. 7, the circuits of the top portion 120t of the second layer 120 will be electrically connected to a via V7 and the a via V8 penetrated through the first layer 110. The via V7, the via V8 are physically contacted and electrically connected to the circuits of the top portion 110t of the first layer 110 to complete the series connection path of the internal circuits of the package structure 100. In here, the bonding pad C1, the bonding pad C2, the bonding pad C3, the bonding pad C4, the bonding pad C5, the bonding pad C6 and the via V1, the via V2, the via V3, the via V4, the via V5, the via V6, the via V7, the via V8 may be formed by a suitable conductive material (such as copper).

It should be noted that the circuit areas not illustrated in the figures are only illustrative drawings, and these circuits can be added, cancelled, or adjusted according to actual design requirements, therefore, these circuits are not used to limit the disclosure.

In this embodiment, the resonator 122 and the chip 123 are located at the same level, in

other words, an orthographic projection of the resonator 122 on the third layer 130 is not overlapped with an orthographic projection of the chip 123 on the third layer 130, therefore, a thickness of the second layer 120 can be reduced, which further has the advantage of thinness, but the disclosure is not limited thereto. In other embodiments, there may be different configuration relationship between the resonator 122 and the chip 123. Another configuration relationship will be further described below.

It is to be noted that the following embodiments use the reference numerals and a part of the contents of the above embodiment, and the same or similar reference numerals are used to denote the same or similar elements, and the description of the same technical content is omitted. For the description of the omitted part, reference may be made to the above embodiments, and details are not described in the following embodiments.

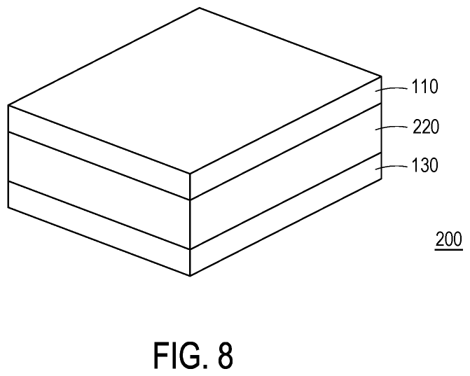

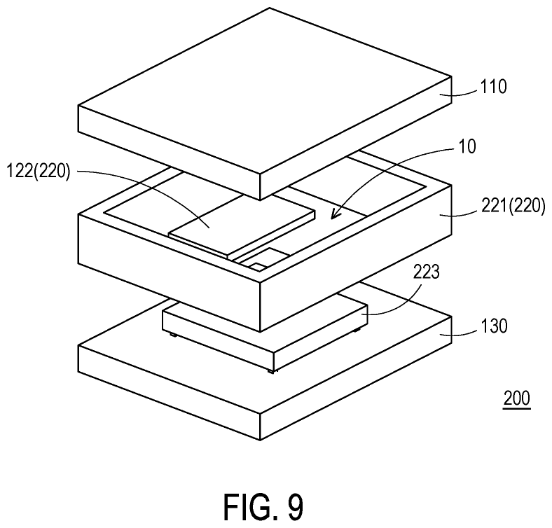

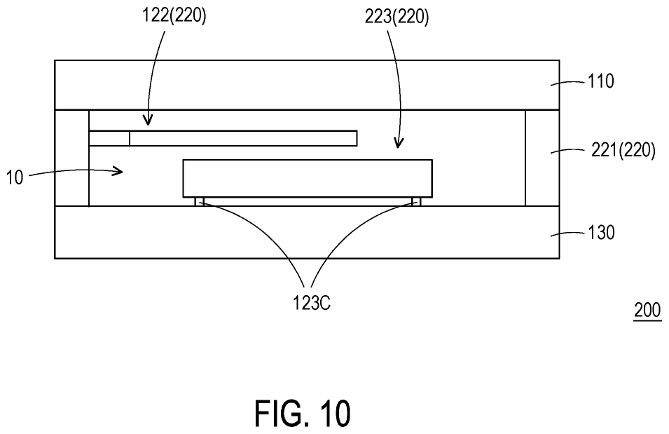

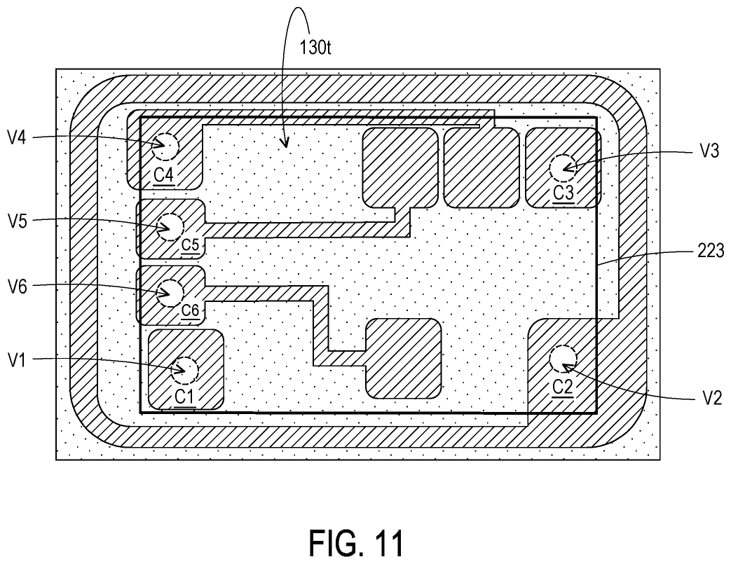

FIG. 8 is a schematic external view of a package structure according to another embodiment of the disclosure. FIG. 9 is a schematic exploded view of FIG. 8. FIG. 10 is a schematic side view of the interior of FIG. 8. FIG. 11 is a schematic top view of the top portion of the third layer in FIG. 8.

Referring to FIG. 8 to FIG. 11, compared with the package structure 100 of the aforementioned embodiment, in this embodiment, a chip 223 of a second layer 220 of a package structure 200 is located below the resonator 122, in other words, an orthographic projection of the resonator 122 on the third layer 130 is partially overlapped an orthographic projection of chip 223 on the third layer 130, therefore, a thickness of the second layer 220 of the package structure 200 will be greater than the thickness of the second layer 120 of the package structure 100. In addition, compared with the package structure 100, the package structure 200 of this embodiment can use a larger chip 223 to provide another design flexibility, as shown in FIG. 11, but the disclosure is not limited thereto. It should be noted that FIG. 9 only clearly illustrates the bonding position of the chip 223 through an exploded view, and does not be represented that it is included in the third layer 130. As shown in FIG. 10, after assembly, the chip 223 is included in the second layer 220.

In this embodiment, the corresponding connection relationships between the bonding pad C1, the bonding pad C2, the bonding pad C3, the bonding pad C4, the bonding pad C5, the bonding pad C6 and the via V1, the via V2, the via V3, the via V4, the via V5, the via V6 are similar to FIG. 4B, and other portions not shown can also be designed with a circuit configuration similar to that of FIG. 4A and FIG. 4C to FIG. 4F, which will not be described.

It should be noted that the above two embodiments are only illustrative. The disclosure does not limit the configuration relationship between the resonator and the chip. As long as the chip is arranged in the stacked structure to achieve a complete protection effect within the scope of the disclosure.

Based on the above, through the design of the stacked structure and the rectangular accommodation portion, the disclosure can reliably encapsulate the resonator and the chip and ensure that the conductive components on the chip are completely protected, thereby the probability of the product failure is effectively reduced while the thinness of product performance is achieved.

Although the disclosure has been described in detail with reference to the above embodiments, they are not intended to limit the disclosure. Those skilled in the art should understand that it is possible to make changes and modifications without departing from the spirit and scope of the disclosure. Therefore, the protection scope of the disclosure shall be defined by the following claims.

What is claimed is:

1. A package structure, comprising:
a first layer;
a second layer, comprising an outer frame, a resonator and a chip; and
a third layer, wherein the second layer is arranged between the first layer and the third layer, wherein the outer frame, the first layer and the third layer are constituted a rectangular accommodation portion, the resonator and the chip are located in the rectangular accommodation portion, the chip is located at a side of the resonator, and the chip is electrically connected to the third layer and the resonator through a plurality of conductive components on the chip.

2. The package structure according to claim 1, wherein the first layer, the outer frame, the resonator and the third layer are composed of quartz.

3. The package structure according to claim 2, wherein the resonator and the outer frame are an integral structure.

4. The package structure according to claim 1, wherein the first layer, the second layer and the third layer are electrically connected to each other through a plurality of vias.

5. The package structure according to claim 1, wherein the resonator and the chip are located at the same level.

6. A package structure, comprising:
a first layer;
a second layer, comprising an outer frame, a resonator and a chip; and
a third layer, wherein the second layer is arranged between the first layer and the third layer, wherein the outer frame, the first layer and the third layer are constituted a rectangular accommodation portion, the resonator and the chip are located in the rectangular accommodation portion, the chip is located below the resonator, and the chip is electrically connected to the third layer and the resonator through a plurality of conductive components on the chip.

7. The package structure according to claim 6, wherein the first layer, the outer frame, the resonator and the third layer are composed of quartz.

8. The package structure according to claim 7, wherein the resonator and the outer frame are an integral structure.

9. The package structure according to claim 6, wherein the first layer, the second layer and the third layer are electrically connected to each other through a plurality of vias.

10. The package structure according to claim 6, wherein an orthographic projection of the resonator on the third layer is partially overlapped with an orthographic projection of the chip on the third layer.
